(19) United States
(12) Patent Application Publication
(10) Pub. No.: US 2007/0031700 A1
(43) Pub. Date: Feb. 8, 2007

(54) ORGANIC LIGHT EMITTING DIODE

(76) Inventors: Tzung-Fang Guo, Tainan County (TW); Fuh-Shun Yang, Tainan County (TW); Ten-Chin Wen, Tainan County (TW); Yaw-Shyan Fu, Tainan County (TW); Ruey-Min Chen, Tainan County (TW); Chia-Tin Chung, Tainan County (TW); Chin-In Wu, Tainan County (TW)

Correspondence Address: NORTH AMERICA INTELLECTUAL PROPERTY CORPORATION, P.O. BOX 506, MERRIFIELD, VA, 22116, US

(21) Appl. No.: 11/462,038

(22) Filed: Aug. 2, 2006

(30) Foreign Application Priority Data
Aug. 3, 2005 (TW) 094126314

(51) Int. Cl. H01L 51/54; H05B 33/12

(52) U.S. Cl. 428/690; 428/917; 313/504; 313/506; 257/40

(57) ABSTRACT

An organic light emitting diode (OLED) includes a substrate, a first electrode layer, an organic emitting layer, a second electrode layer, and an electron injection layer, in which the electron injection layer is selected from an electron injection layer made from organic molecules, an electron injection layer with nano-grade thickness, or an electron injection layer having dipole moment organic molecules with nano-grade thickness. By utilizing the conformation of the electron injection layer, an OLED having stable operation can be achieved.

### BACKGROUND OF THE INVENTION

1. Field of the Invention

The invention relates to an organic light emitting diode, and more particularly, to an organic light emitting diode capable of providing stronger stability.

2. Description of the Prior Art

The basic structure of organic light emitting diodes includes glass substrates, metal electrodes, electrodes composed of indium tin oxide (ITO), and organic emitting layers, in which the metal electrodes serve as cathodes and the ITO electrodes serve as anodes. When a forward bias voltage is applied between the anode and the cathode, electrons and holes are injected into the organic emitting layer through the metal electrode and the ITO electrode interface. Essentially, the two types of carriers will interact by radioactive means in the organic emitting layer to generate photons and achieve the light emitting characteristics of organic light emitting diodes. Since the transmission of electrons is much faster than the transmission of holes, a hole transport layer is disposed between the anode and the organic emitting layer and/or an electron injection layer is disposed between the organic emitting layer and the cathode to create a balance between the transmission of electrons and holes.

Organic light emitting diodes today, depending on the material of the emitting layer being used, are categorized into macromolecular light emitting diodes and micromolecular light emitting diodes. Typically, the electron injection layer of the micromolecular organic light emitting diodes is composed of lithium fluoride, whereas the electron injection layer of the macromolecular organic light emitting diodes is omitted due to limitations of the fabrication process. Instead, cathodes composed of barium, calcium, or magnesium are fabricated directly on the emitting layer of the macromolecular organic light emitting diodes.

However, materials utilized for fabricating the cathodes of macromolecular light emitting diodes are often likely to damage the entire light emitting device. Hence, finding an electron injection layer suitable for both macromolecular and micromolecular light emitting diodes is critically important.

### SUMMARY OF THE INVENTION

It is therefore an objective of the present invention to provide an organic light emitting diode with stronger stability.

It is one aspect of the present invention to provide an organic light emitting diode for preventing damages caused by the material utilized for fabricating electrodes, such that the performance of the organic light emitting diode can be significantly enhanced.

According to the present invention, an organic light emitting diode having a substrate, a first electrode layer, an organic emitting layer, a second electrode layer, and an electron injection layer is disclosed. The first electrode layer is disposed on the substrate, the organic emitting layer is disposed on the first electrode layer, and the second electrode layer is disposed on the organic emitting layer.

The electron injection layer is disposed between the second electrode layer and the organic emitting layer, in which the electron injection layer includes high polymers or micromolecular organic materials. Preferably, the high polymers satisfy one of the following conditions: (a) comprising aromatic groups or fused aromatic groups on a side chain; (b) comprising C—O bonds on a main chain or on a side chain; and (c) comprising Si—O bonds on a main chain or on a side chain. The micromolecular organic materials on the other hand satisfy one of the following conditions: (d) comprising fused aromatic groups; (e) comprising C—O bonds; and (f) comprising multi-F group compound.

According to the organic light emitting diode of the first embodiment of the present invention, the high polymers satisfy the condition (a) stated above includes formula (A) and a material selected from the group consisting of formula (B), formula (C), and formula (D):

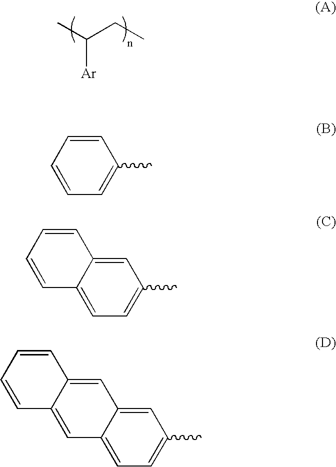

Specifically, formula (B) comprises phenyl of an electron accepting group, formula (C) comprises naphthyl, and formula (D) comprises anthracenyl of electron accepting group.

The high polymers satisfy the condition (b) comprise an ether group or an ester group, such as a material selected from the group consisting of polyethylene oxide (PEO), polyacrylate, polyglycol, polycarbonate, poly(4-vinylphenol) (PVP), polyvinyl alcohol (PVA), and polyvinyl acetate. Additionally, the higher polymers satisfy the condition (c) comprises siloxane, such as poly(dimethyl siloxane).

The micromolecular organic materials satisfy the condition (d) comprise fullerene (C60;70 derivative) or cyanine dye. The micromolecular organic materials satisfy the condition (e) are selected from the group consisting of acetate and metal complex, in which acetate comprises metal acetate complex, and metal complex comprises ether metal complex or metal olefine complex. The micromolecular organic materials satisfy the condition (f) comprise metal fluoride or fluoride compound.

According to a second embodiment of the present invention, another organic light emitting diode is disclosed. The organic light emitting diode includes a substrate; a first electrode layer, disposed on the substrate; an organic emitting layer, disposed on the first electrode layer; a second electrode layer, disposed on the organic emitting layer; and a nano-grade electron injection layer including organic molecules with dipole moments, disposed between the second electrode layer and the organic emitting layer.

According to the organic light emitting diode of the second embodiment of the present invention, the thickness of the nano-grade electron injection layer including organic molecules with dipole moments is less than 20 nanometers.

According to the organic light emitting diode of the second embodiment of the present invention, the nano-grade electron injection layer including organic molecules with dipole moments comprises high polymers or micromolecular organic materials, in which the high polymers satisfy one of the following conditions: (a) comprising aromatic groups or fused aromatic groups on a side chain; (b) comprising C—O bonds on a main chain or on a side chain; and (c) comprising Si—O bonds on a main chain or on a side chain. The micromolecular organic materials on the other hand, satisfy one of the following conditions: (d) comprising fused aromatic groups; (e) comprising C—O bonds; and (f) comprising multi-F group compound.

According to the organic light emitting diode of the second embodiment of the present invention, the high polymers satisfy the condition (a) includes formula (A) and a material selected from the group consisting of formula (B), formula (C), and formula (D):

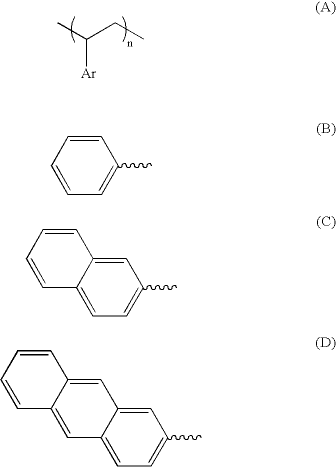

Specifically, formula (B) comprises phenyl of an electron accepting group, formula (C) comprises naphthyl, and formula (D) comprises anthracenyl of electron accepting group.

The high polymers satisfy the condition (b) comprise an ether group or an ester group, such as a material selected from the group consisting of polyethylene oxide (PEO), polyacrylate, polyglycol, polycarbonate, poly(4-vinylphenol) (PVP), polyvinyl alcohol (PVA), and polyvinyl acetate. Additionally, the higher polymers satisfy the condition (c) comprises siloxane, such as poly(dimethyl siloxane).

The micromolecular organic materials satisfy the condition (d) comprise fullerene (C60;70 derivative) or cyanine dye. The micromolecular organic materials satisfy the condition (e) are selected from the group consisting of acetate and metal complex, in which acetate comprises metal acetate complex and metal complex comprises ether metal complex or metal olefine complex. The micromolecular organic materials satisfy the condition (f) comprise metal fluoride or fluoride compound.

According to the organic light emitting diode of either embodiment, the organic emitting layer is composed of poly(2-methoxy-5-(2′-ethylhexyloxy)-1,4-phynylene vinylene) (MEH-PPV) or tris(8-hydroxylquinoline)aluminum (Alq3). The second electrode layer comprises aluminum, and the first electrode layer comprises indium tin oxide (ITO). Additionally, a hole transport layer is disposed between the first electrode layer and the organic emitting layer, in which the hole transport layer comprises poly(3,4-ethylenedioxy thiophene):poly styrenesulfonate (PEDOT:PSS). The substrate can be a glass substrate or a flexible substrate.

Overall, the present invention discloses an electron injection layer of unique material and structure, in which the electron injection layer can be applied to macromolecular or micromolecular light emitting diodes. Ultimately, the stability of the light emitting device can be significantly improved.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-view of a light emitting diode according the first embodiment of the present invention.

FIG. 2 is a curve diagram illustrating the bias voltage, current, and light intensity (I-L-V) of Example 1 and Comparative Example 1.

FIG. 3 is a curve diagram illustrating the voltage and current density of Example 2, Comparative Example 2, and Comparative Example 3.

FIG. 4 is curve diagram illustrating the voltage and luminance of the Example 2, Comparative Example 2, and Comparative Example 3.

FIG. 5 is a perspective diagram showing a cross-section of an organic light emitting diode according the second embodiment of the present invention.

FIG. 6 is a perspective diagram illustrating an expansion of the portion IV from FIG. 5.

### DETAILED DESCRIPTION

Certain terms are used throughout the following description and claims to refer to particular system components. As one skilled in the art will appreciate, consumer electronic equipment manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . ” The terms “couple” and “couples” are intended to mean either an indirect or a direct electrical connection. Thus, if a first device couples to a second device, that connection may be through a direct electrical connection, or through an indirect electrical connection via other devices and connections.

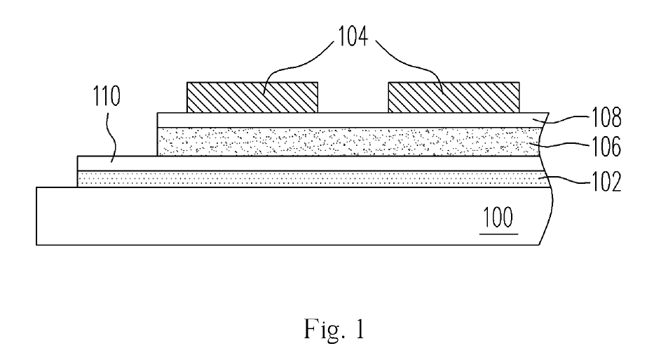

Please refer to FIG. 1. FIG. 1 is a cross-view of a light emitting diode according the first embodiment of the present invention. As shown in FIG. 1, the light emitting diode includes a substrate 100, a first electrode layer 102, a second electrode layer 104, an organic emitting layer 106, and an electron injection layer 108. The first electrode layer 102 is disposed on the substrate 100 and composed of indium tin oxide (ITO). Additionally, the organic emitting layer 106 is disposed on the first electrode layer 102, the second electrode layer 104 is disposed above the organic emitting layer 106, and the electron injection layer 108 is disposed between the second electrode layer 104 and the organic emitting layer 106.

In order to stabilize the light emitting property of the light emitting diodes, the coating process of the electron injection layer 108 is adjusted according to various applications where the electron injection layer 108 is being utilized, such as applied to micromolecular light emitting diodes or to high polymer light emitting diodes. In other words, different coating processes are utilized depending on the property of different molecules. For instance, a spin coating process is performed to fabricate micromolecular light emitting diodes, and an evaporation process is often performed to fabricate high polymer light emitting diodes. By utilizing different fabrication processes to fabricate the electron injection layer of organic light emitting diodes, the present invention is able to utilize the electron injection layer to adjust the band gap between the negative electrode and the organic layers, such as the electron transport layer or the organic emitting layer, and also provide a path for the injection of electrons, thereby increasing the emitting efficiency of the device.

Referring back to FIG. 1, the electron injection layer 108 is composed of high polymers or micromolecular organic materials, in which the high polymers satisfy one of the following conditions: (a) including aromatic groups or fused aromatic groups on a side chain; (b) including C—O bonds on a main chain or on a side chain; (c) including Si—O bonds on a main chain or on a side chain. Additionally, the micromolecular organic materials satisfy one of the following conditions: (d) including fused aromatic groups; (e) comprising C—O bonds; and (f) including multi-F group compound.

For example, high polymers satisfy the condition (a) include a formula (A), and a material selected from the group consisting of formulae (B), formula (C), and formula (D) shown below.

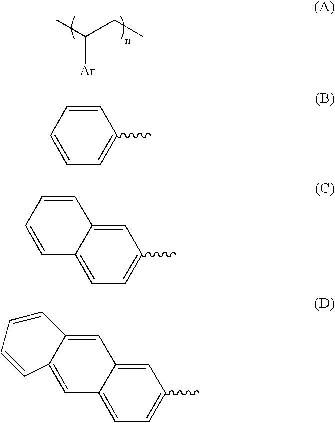

As shown above, formula (B) includes phenyl of an electron accepting group, formula (C) includes naphthyl, and formula (D) includes anthracenyl of electron accepting group.

According to the first embodiment of the present invention, the high polymers satisfy the condition (b) include an ether group or an ester group, such as a material selected from the group consisting of polyethylene oxide (PEO), polyacrylate, polyglycol, polycarbonate, poly(4-vinylphenol) (PVP), polyvinyl alcohol (PVA), and polyvinyl acetate. Additionally, the higher polymers satisfy the condition (c) described previously include siloxane, such as poly(dimethyl siloxane).

According to the first embodiment of the present invention, micromolecular organic materials satisfy the condition (d) include fullerene (C60;70 derivative) or cyanine dye. Additionally, micromolecular organic materials satisfy the condition (e) are selected from the group consisting of acetate and metal complex, in which acetate includes metal acetate complex, and metal complex includes ether metal complex or metal olefine complex. Moreover, micromolecular organic materials satisfy the condition (f) include metal fluoride or fluoride compound.

Referring back to the FIG. 1, the organic emitting layer 106 is composed of poly(2-methoxy-5-(2′-ethylhexyloxy)-1,4-phynylene vinylene) (MEH-PPV) or tris(8-hydroxylquinoline)aluminum (Alq3), and the second electrode layer 104 is composed of aluminum. Additionally, a hole transport layer 110 is disposed between the first electrode layer 102 and the organic emitting layer 106, in which the hole transport layer 110 is composed of poly(3,4-ethylenedioxy thiophene): poly styrenesulfonate (PEDOT:PSS). Preferably, the substrate 100 is a glass substrate or a flexible substrate.

By utilizing a spin coating process, the electron injection layer 108 can be fully integrated on the organic emitting layer 106 for forming a macromolecular organic light emitting diode. A cathode composed of aluminum can be further integrated with the electron injection layer 108 to prevent the organic light emitting diode from any damage, thereby improving the overall stability of the device. A comparison between examples relating to the first embodiment of the present and comparative examples relating to the conventional organic light emitting diodes is discussed in the following section.

### EXAMPLE 1

First, a polymer light emitting diode (PLED) composed of a glass substrate, an ITO anode, an MEH-PPV organic emitting layer, and an aluminum cathode is provided, in which a hole transport layer composed of PEDOT:PSS is disposed by spin coating on the ITO anode and between the ITO anode and the MEH-PPV organic emitting layer. Subsequently, a coating process is performed under 6000 rpm to form an electron injection layer composed of PEO on the surface of the MEH-PPV organic emitting layer, in which the polyethylene oxide of the electron injection layer is prepared from a 0.01 wt % PEO/acetonitrile anhydrous solution. Next, an evaporation process is performed to form an aluminum electrode on the PEO film. The active pixel area of the polymer light emitting diode is 0.06 cm². In addition to the PEDOT:PSS utilized for coating each layer of the PLED, the entire device is fabricated under a nitrogen-rich environment to prevent damage to the device from other harmful materials.

### COMPARATIVE EXAMPLE 1

In contrast to the Example 1, the polymer light emitting diode of the present example does not include an electron injection layer composed of PEO. The other layers of the polymer light emitting diode are equivalent to the ones described in Example 1.

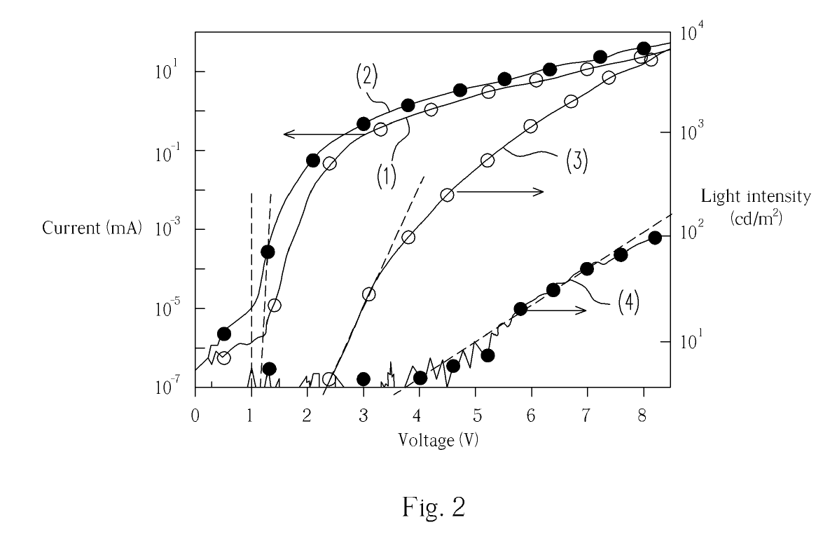

Please refer to FIG. 2. FIG. 2 is a curve diagram illustrating the bias voltage, current, and light intensity (I-L-V) of Example 1 and Comparative Example 1, in which the solid circle represents the Comparative Example 1 without having the PEO layer, whereas the open circle represents the Example 1 having the PEO layer. As shown in FIG. 2, curve (1) indicates a relationship between the bias voltage and the current of the Example 1, and curve (2) indicates a relationship between the bias voltage and the current of the Comparative Example 1. Evidently, the currents represented by both curves are relatively close. Additionally, curve (3) indicates a relationship between the bias voltage and light intensity of the Example 1, and curve (4) indicates a relationship between the bias voltage and light intensity of the Comparative Example 1. It can be noted that when the driving voltage is approximately 2.40 volts greater than the turn-on voltage, the light intensity of the polymer light emitting diode from Example 1 will be two orders higher than the light intensity of the polymer light emitting diode of the Comparative Example 1.

### EXAMPLE 2

A micromolecular light emitting diode having a glass substrate, a 1500 angstrom ITO anode, a 600 angstrom hole injection layer composed of CuPc, a 100 angstrom hole transport layer composed of NPB, a 600 angstrom organic emitting material composed of Rubrene, a 60 angstrom electron injection layer composed of PEO, and a 1200 angstrom aluminum cathode is provided. According to the present example, CuPc, NPB, Rubrene, PEO, and aluminum are first vacuumed to 10⁻⁶ Torr in an evaporation apparatus, and then formed on the glass substrate via evaporation.

### COMPARATIVE EXAMPLE 2

In contrast to the Example 2, the micromolecular light emitting diode of the present example does not include an electron injection layer. However, other layers of the device remain to be the same as Example 2.

### COMPARATIVE EXAMPLE 3

The electron injection layer of the present example is composed of lithium fluoride, whereas other layers of the device remain to be the same as the Example 2.

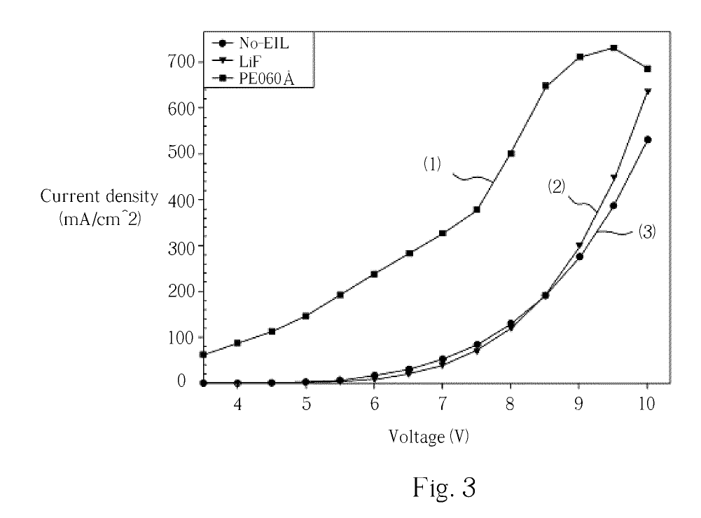

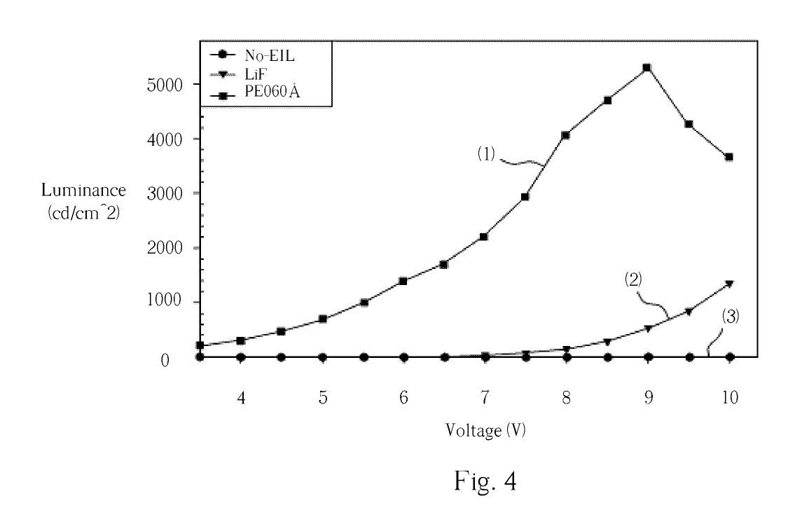

Please refer to FIG. 3 and FIG. 4. FIG. 3 is a curve diagram illustrating the voltage and current density of Example 2, Comparative Example 2, and Comparative Example 3, and FIG. 4 is curve diagram illustrating the voltage and luminance of the Example 2, Comparative Example 2, and Comparative Example 3. In the FIG. 3, Curve (1) indicates a relationship between the voltage and current density of the 60 angstrom PEO layer from Example 2, curve (2) indicates a relationship between the voltage and current density of the lithium fluoride electron injection layer from Comparative Example 3, and curve (3) indicates a relationship between the voltage and current density of Example 2, in which no electron injection layer is present. Additionally, in the FIG. 4, curve (1) indicates a relationship between the voltage and luminance of the 60 angstrom PEO layer from Example 2, curve (2) from FIG. 4 indicates a relationship between the voltage and luminance of the lithium fluoride electron injection layer from Comparative Example 3, and curve (3) indicates a relationship between the voltage and current density of Example 2, in which no electron injection layer is present.

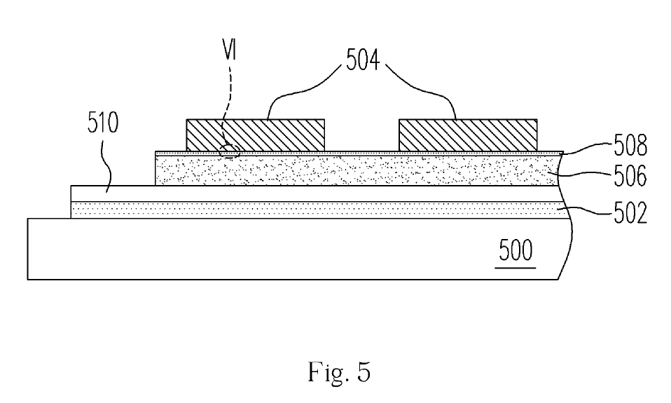

Please refer to FIG. 5. FIG. 5 is a perspective diagram showing a cross-section of an organic light emitting diode according the second embodiment of the present invention. As shown in FIG. 5, the organic light emitting diode includes a substrate 500, a first electrode layer 502, a second electrode layer 504, an organic emitting layer 506, a nano-grade electron injection layer 508 having organic molecules with dipole moment, and a hole transport layer 510 disposed between the first electrode layer 502 and the organic emitting layer 506. Preferably, the electron injection layer 508 is composed of a nano-grade layer having organic molecules with dipole moment. In other words, the thickness of the electron injection layer 508 is equivalent to a nano-grade thickness, such as less than 20 nanometers, or 200 angstroms, and preferably between 10 angstroms to 75 angstroms.

In order to improve the stability of the organic light emitting device, the electron injection layer 508 is composed of high polymers or micromolecular organic materials, in which the high polymers satisfy one of the following conditions: (a) including aromatic groups or fused aromatic groups on a side chain; (b) including C—O bonds on a main chain or on a side chain; (c) including Si—O bonds on a main chain or on a side chain. Additionally, the micromolecular organic materials satisfy one of the following conditions: (d) including fused aromatic groups; (e) comprising C—O bonds; and (f) including multi-F group compound.

For example, high polymers satisfy the condition (a) include formula (A) and a material selected from the group consisting of formulae (B), formula (C), and formula (D) shown below.

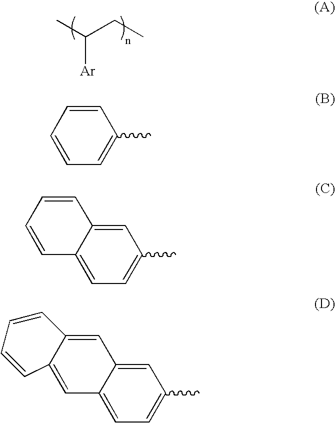

As shown above, formula (B) includes phenyl of an electron accepting group, formula (C) includes naphthyl, and formula (D) includes anthracenyl of electron accepting group.

According to the second embodiment of the present invention, the high polymers satisfy the condition (b) include an ether group or an ester group, such as a material selected from the group consisting of polyethylene oxide (PEO), polyacrylate, polyglycol, polycarbonate, poly(4-vinylphenol) (PVP), polyvinyl alcohol (PVA), and polyvinyl acetate. Additionally, the higher polymers satisfy the condition (c) described previously include siloxane, such as poly(dimethyl siloxane).

According to the second embodiment of the present invention, micromolecular organic materials satisfy the condition (d) include fullerene (C60;70 derivative) or cyanine dye. Additionally, micromolecular organic materials satisfy the condition (e) are selected from the group consisting of acetate and metal complex, in which acetate includes metal acetate complex, and metal complex includes ether metal complex or metal olefine complex. Moreover, micromolecular organic materials satisfy the condition (f) include metal fluoride or fluoride compound.

Mechanism:

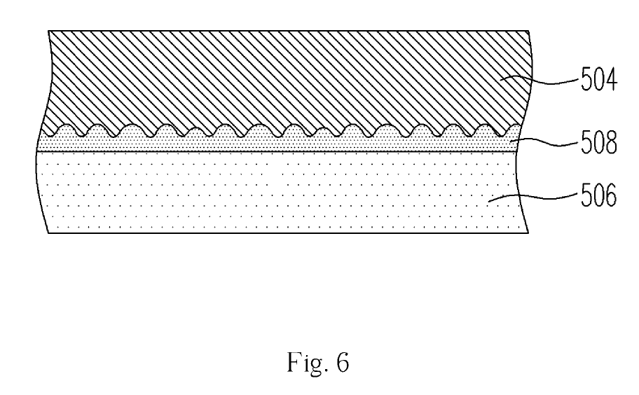

Please refer to FIG. 6. FIG. 6 is a perspective diagram illustrating an expansion of the portion IV from FIG. 5. Despite the fact that the PEO being utilized in the electron injection layer 508 is a poor conducting material, the electron injection layer 508, due to its nano-grade nature, is able to interact with the second electrode layer 504 and induce an electron tunneling effect when an evaporation process is performed on the second electrode layer 504. For instance, when the nano-grade electron injection layer 508 having organic molecules with dipole moment is composed of PEO and the second electrode layer 504 is composed of aluminum, an interaction will take place at the interface between the two layers and form the following bond:
—(CH₂CH₂O)ₙ—:AI

Overall, the present invention discloses an electron injection layer of unique material and structure, in which the electron injection layer can be applied to macromolecular or micromolecular light emitting diodes. Ultimately, the stability of the light emitting device can be significantly improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light emitting diode, comprising:
a substrate;
a first electrode layer, disposed on the substrate;
an organic emitting layer, disposed on the first electrode layer;
a second electrode layer, disposed on the organic emitting layer; and
an electron injection layer, disposed between the second electrode layer and the organic emitting layer, the electron injection layer comprises high polymers or micromolecular organic materials, wherein the high polymers satisfy one of the following conditions:
(a) comprising aromatic groups or fused aromatic groups on a side chain;
(b) comprising C—O bonds on a main chain or on a side chain;
(c) comprising Si—O bonds on a main chain or on a side chain; and the micromolecular organic materials satisfy one of the following conditions:
(d) comprising fused aromatic groups;
(e) comprising C—O bonds; and
(f) comprising multi-F group compound.

2. The organic light emitting diode of claim 1, wherein the high polymers satisfy the condition (a) comprise: formula (A); and a material selected from the group consisting of formula (B), formula (C), and formula (D): 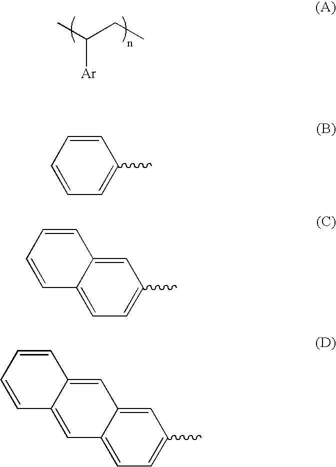
wherein formula (B) comprises phenyl of an electron accepting group, formula (C) comprises naphthyl, and formula (D) comprises anthracenyl of electron accepting group.

3. The organic light emitting diode of claim 1, wherein the high polymers satisfy the condition (b) comprise an ether group or an ester group.

4. The organic light emitting diode of claim 3, wherein the high polymers satisfy the condition (b) are selected from the group consisting of polyethylene oxide (PEO), polyacrylate, polyglycol, polycarbonate, poly(4-vinylphenol) (PVP), polyvinyl alcohol (PVA), and polyvinyl acetate.

5. The organic light emitting diode of claim 1, wherein the higher polymers satisfy the condition (c) comprises siloxane.

6. The organic light emitting diode of claim 5, wherein the higher polymers satisfy the condition (c) comprises poly(dimethyl siloxane).

7. The organic light emitting diode of claim 1, wherein the micromolecular organic materials satisfy the condition (d) comprise fullerene (C60;70 derivative) or cyanine dye.

8. The organic light emitting diode of claim 1, wherein the micromolecular organic materials satisfy the condition (e) are selected from the group consisting of acetate and metal complex.

9. The organic light emitting diode of claim 8, wherein acetate comprises metal acetate complex.

10. The organic light emitting diode of claim 8, wherein metal complex comprises ether metal complex or metal olefine complex.

11. The organic light emitting diode of claim 1, wherein the micromolecular organic materials satisfy the condition (f) comprise metal fluoride or fluoride compound.

12. An organic light emitting diode, comprising:
a substrate;
a first electrode layer, disposed on the substrate;
an organic emitting layer, disposed on the first electrode layer;
a second electrode layer, disposed on the organic emitting layer; and
a nano-grade electron injection layer including organic molecules with dipole moments, disposed between the second electrode layer and the organic emitting layer.

13. The organic light emitting diode of claim 12, wherein the thickness of the nano-grade electron injection layer including organic molecules with dipole moments is less than 20 nanometers.

14. The organic light emitting diode of claim 12 or claim 13, wherein the nano-grade electron injection layer including organic molecules with dipole moments comprises high polymers or micromolecular organic materials, wherein the high polymers satisfy one of the following conditions:
(a) comprising aromatic groups or fused aromatic groups on a side chain;
(b) comprising C—O bonds on a main chain or on a side chain;
(c) comprising Si—O bonds on a main chain or on a side chain; and the micromolecular organic materials satisfy one of the following conditions:
(d) comprising fused aromatic groups;
(e) comprising C—O bonds; and
(f) comprising multi-F group compound.

15. The organic light emitting diode of claim 14, wherein the high polymers satisfy the condition (a) comprise: formula (A); and a material selected from the group consisting of formula (B), formula (C), and formula (D): 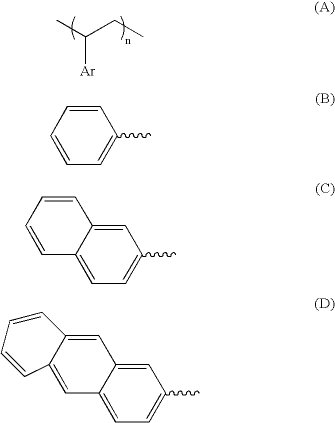
wherein formula (B) comprises phenyl of an electron accepting group, formula (C) comprises naphthyl, and formula (D) comprises anthracenyl of electron accepting group.

16. The organic light emitting diode of claim 14, wherein the high polymers satisfy the condition (b) comprise an ether group or an ester group.

17. The organic light emitting diode of claim 16, wherein the high polymers satisfy the condition (b) are selected from the group consisting of polyethylene oxide (PEO), polyacrylate, polyglycol, polycarbonate, poly(4-vinylphenol) (PVP), polyvinyl alcohol (PVA), and polyvinyl acetate.

18. The organic light emitting diode of claim 14, wherein the higher polymers satisfy the condition (c) comprises siloxane.

19. The organic light emitting diode of claim 18, wherein the higher polymers satisfy the condition (c) comprises poly(dimethyl siloxane).

20. The organic light emitting diode of claim 14, wherein the micromolecular organic materials satisfy the condition (d) comprise fullerene (C60;70 derivative) or cyanine dye.

21. The organic light emitting diode of claim 14, wherein the micromolecular organic materials satisfy the condition (e) are selected from the group consisting of acetate and metal complex.

22. The organic light emitting diode of claim 21, wherein acetate comprises metal acetate complex.

23. The organic light emitting diode of claim 21, wherein metal complex comprises ether metal complex or metal olefine complex.

24. The organic light emitting diode of claim 14, wherein the micromolecular organic materials satisfy the condition (f) comprise metal fluoride or fluoride compound.

25. The organic light emitting diode of claim 1 or claim 12, wherein the organic emitting layer comprises poly(2-methoxy-5-(2′-ethylhexyloxy)-1,4-phynylene vinylene) (MEH-PPV) or tris(8-hydroxylquinoline)aluminum (Alq3).

26. The organic light emitting diode of claim 1 or claim 12, wherein the second electrode layer comprises aluminum.

27. The organic light emitting diode of claim 1 or claim 12, wherein the first electrode layer comprises indium tin oxide (ITO).

28. The organic light emitting diode of claim 1 or claim 12 further comprising a hole transport layer disposed between the first electrode layer and the organic emitting layer.

29. The organic light emitting diode of claim 28, wherein the hole transport layer comprises poly(3,4-ethylenedioxy thiophene):poly styrenesulfonate (PEDOT:PSS).

30. The organic light emitting diode of claim 1 or claim 12, wherein the substrate comprises a glass substrate or a flexible substrate.
